(19) United States
(12) Patent Application Publication
(10) Pub. No.: US 2026/0130241 A1
(43) Pub. Date: May 7, 2026

(54) PACKAGE STRUCTURE AND MANUFACTURING METHOD THEREOF

(71) Applicant: Powertech Technology Inc., Hsinchu County (TW)

(72) Inventors: Shang-Yu Chang Chien, Hsinchu County (TW); Yi-Kai Fu, Hsinchu County (TW)

(73) Assignee: Powertech Technology Inc., Hsinchu County (TW)

(21) Appl. No.: 19/361,013

(22) Filed: Oct. 17, 2025

(30) Foreign Application Priority Data
Nov. 6, 2024 (TW) 113142461

(51) Int. Cl. H01L 23/538; H01L 21/48; H01L 23/00; H01L 23/367; H01L 25/03

(52) U.S. Cl. CPC H10W 70/611; H10W 40/22; H10W 70/093; H10W 90/00; H10W 90/401; H10W 72/07354; H10W 72/347; H10W 72/877; H10W 74/15; H10W 90/724; H10W 90/733; H10W 90/734

(57) ABSTRACT

Provided is a package structure, which includes a substrate, an interposer module, and a chip module. The interposer module is disposed on the substrate. The interposer module includes a first insulating layer, a second insulating layer, and multiple dummy terminals. The first insulating layer is disposed between the second insulating layer and the substrate. The multiple dummy terminals are in direct contact with the first insulating layer and the substrate. The chip module is disposed on the interposer module and is electrically connected to the substrate through the interposer module. Also provided is a manufacturing method of a package structure. The plurality of external terminals include a plurality of functional components. The substrate is disposed between the plurality of dummy terminals and the plurality of external terminals, and the plurality of dummy terminals are electrically insulated the plurality of functional components.

### CROSS-REFERENCE TO RELATED APPLICATION

This application claims the priority benefit of Taiwan application serial no. 113142461, filed on Nov. 6, 2024. The entirety of the above-mentioned patent application is hereby incorporated by reference herein and made a part of the disclosure.

### BACKGROUND

### Technical Field

The disclosure relates to a package structure and a manufacturing method thereof.

### Description of Related Art

With the advancement of technology, the requirements for electronic products in the market are also increasing day by day. For example, how to ensure that the package structure has good quality has become a current topic of research.

### SUMMARY

The disclosure provides a package structure and a manufacturing method thereof, of which a yield is effectively improved, ensuring good quality.

A package structure of the disclosure includes a substrate, an interposer module, a chip module, and a plurality of external terminals. The interposer module is disposed on the substrate. The interposer module includes a first insulating layer, a second insulating layer, and multiple dummy terminals. The first insulating layer is disposed between the second insulating layer and the substrate. The multiple dummy terminals are in direct contact with the first insulating layer and the substrate. The chip module is disposed on the interposer module and is electrically connected to the substrate through the interposer module. The plurality of external terminals include a plurality of functional components. The substrate is disposed between the plurality of dummy terminals and the plurality of external terminals, and the plurality of dummy terminals are electrically insulated the plurality of functional components.

A manufacturing method of a package structure of the disclosure at least includes: a substrate is provided; an interposer module including multiple dummy terminals is provided; the interposer module is disposed on the substrate through multiple dummy terminals; a chip module is provided; and the chip module is disposed on the interposer module, the interposer module is singulated, and the chip module is electrically connected to the substrate through the interposer module.

Based on the above, since the number of processes that the chip module goes through may be decreased, the risk of yield loss in the process may be reduced, and at the same time, the stress in the process may be disperse by the design of dummy terminals. Accordingly, the yield of the package structure of the disclosure is effectively improved, thereby ensuring good quality.

In order to make the features and advantages of the disclosure more comprehensible, the following examples are given and described in detail with the accompanying drawings as follows.

### BRIEF DESCRIPTION OF THE DRAWINGS

FIG. 1A to FIG. 1G are partial cross-sectional schematic diagrams of parts of a manufacturing method of a package structure according to an embodiment of the disclosure.

FIG. 2, FIG. 3, FIG. 4, FIG. 5, FIG. 6, FIG. 7, and FIG. 8 are partial cross-sectional schematic diagrams of a package structure according to some embodiments of the disclosure.

### DESCRIPTION OF THE EMBODIMENTS

Directional terms used herein (such as up, down, right, left, front, back, top, bottom) are only used with reference to the drawings and are not intended to imply absolute orientation.

Unless expressly stated otherwise, any method described herein is in no way intended to be construed as requiring that the steps are to be performed in a particular order.

The disclosure will be described more fully with reference to the drawings of the embodiment. However, the disclosure may also be embodied in various forms and should not be limited to the embodiments described herein. The thickness, dimension, or size of layers or regions in the drawings are exaggerated for clarity. The same or similar reference numerals indicate the same or similar components, and will not be repeated one by one in the following paragraphs.

It will be understood that, although the terms “first”, “second”, “third”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section.

Unless otherwise stated, the term “between” used to define numerical ranges in the disclosure is intended to cover a range equal to and between the endpoint values. For example, the dimension range is between the first value and the second value, which means that the dimension range may cover the first value, the second value and any value between the first value and the second value.

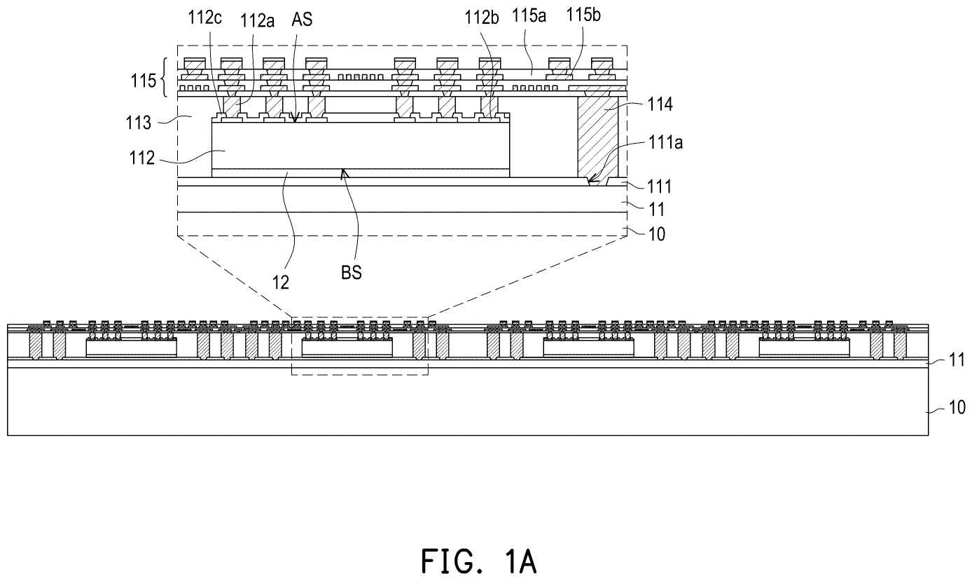

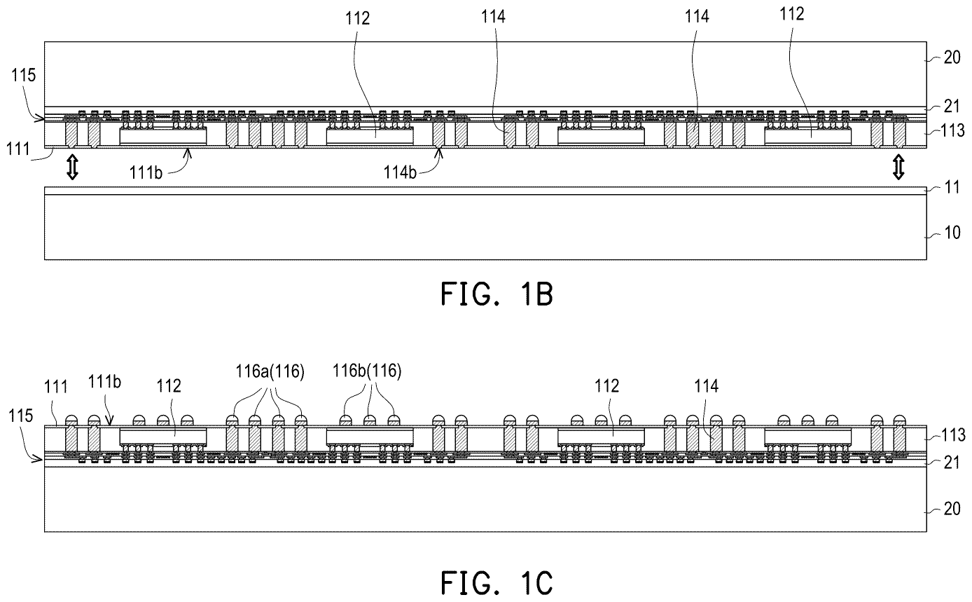

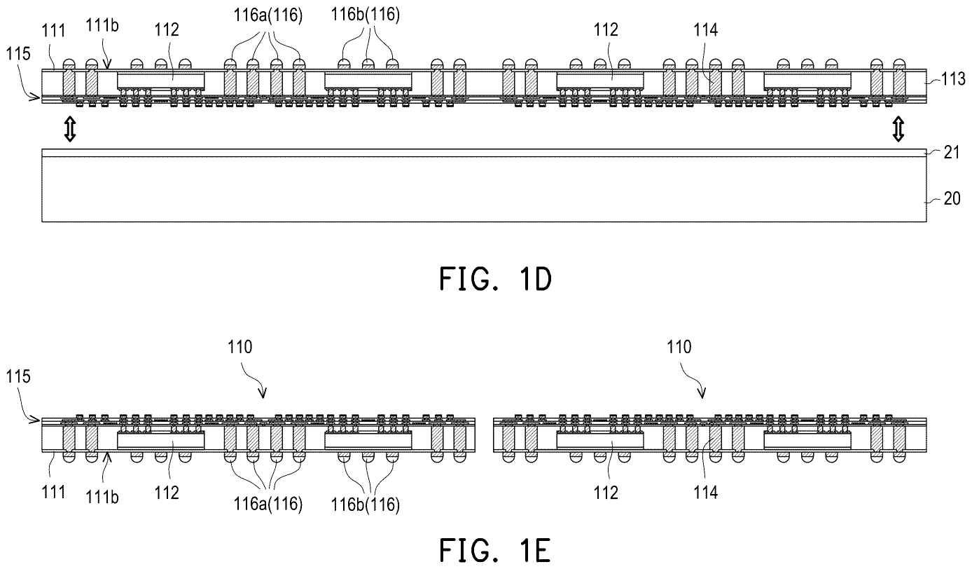

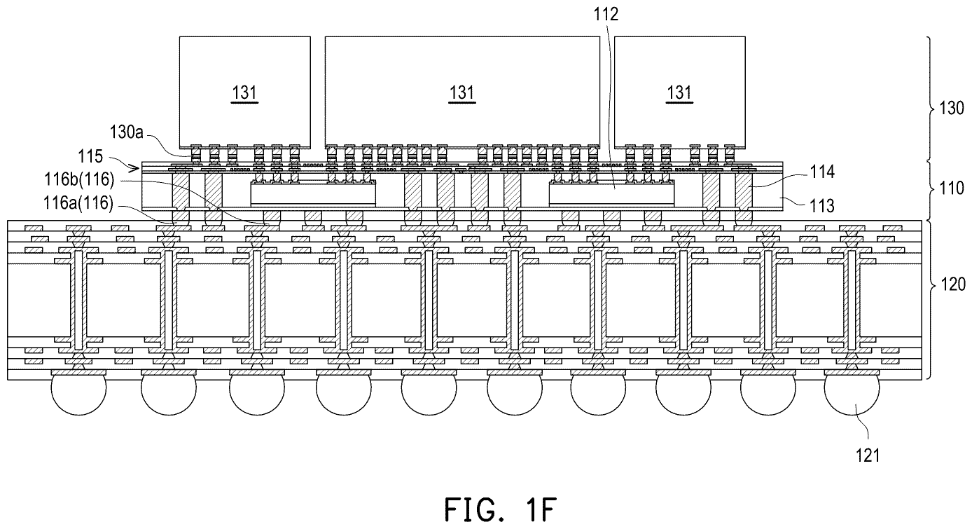

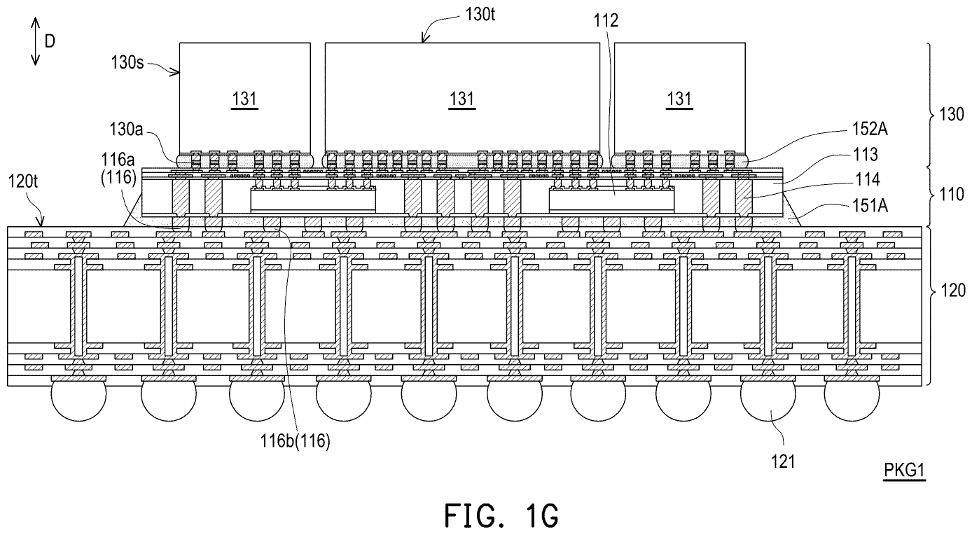

FIG. 1A to FIG. 1G are partial cross-sectional schematic diagrams of parts of a manufacturing method of a package structure according to an embodiment of the disclosure. Please refer to FIG. 1A to FIG. 1E. A manufacturing process of an interposer module 110 may include the following steps. First, a carrier 10 is provided. In some embodiments, the carrier 10 is, for example, a plate made of glass, wafer, metal or other suitable supporting materials, so that the carrier 10 may be configured to carry film layers or components formed thereon.

In the embodiment, a release layer 11 is optionally formed on the carrier 10 to improve the releasability of the structure (such as an intermediate structure in the process) and the carrier 10 in subsequent processes. For example, the release layer 11 may be a light-to-heat-conversion (LTHC) release layer or other suitable release layers, and the disclosure is not limited thereto. In present embodiment, the release layer 11 may not provide adhesion function.

Next, a layered structure 111 is formed on the carrier 10. In the embodiment, the layered structure 111 is a single-layer structure. For example, the layered structure 111 may be made of polyimide, polybenzoxazole (PBO), benzocyclobutene (BCB) or an insulating layer deposited by the like, but the disclosure is not limited thereto. In an embodiment not illustrated, the layered structure 111 may be a suitable redistribution layer (RDL) structure. A top insulating layer and a bottom insulating layer of the redistribution layer structure are insulating layers deposited by polyimide, polybenzoxazole, phenylcyclobutene or the like. The top insulating layer is, for example, a film layer farthest away from the carrier 10 in the redistribution layer structure. The bottom insulating layer is, for example, a film layer closest to the carrier 10 in the redistribution layer structure. In addition, multiple openings 111a may be formed in the layered structure 111 through a suitable method (such as an etching process). Here, the layered structure 111 is, for example, a first insulating layer.

Then, as shown in FIG. 1A, multiple bridge dies 112 are disposed on the carrier 10. In the embodiment, the bridge die 112 has an active surface AS and a back surface BS relative to the active surface AS. The bridge dies 112 are disposed on the layered structure 111 with the active surface AS facing upward. For example, the back surface BS of the bridge die 112 is disposed on the layered structure 111 through an adhesive layer 12. In addition, when the layered structure 111 is a single-layer structure, the adhesive layer 12 may be in direct contact with a top surface of the layered structure 111. When the layered structure 111 is a redistribution layer structure, the adhesive layer 12 may be in direct contact with the top insulating layer of the layered structure 111.

In an embodiment, the adhesive layer 12 may be a die attach film (DAF). However, the disclosure is not limited thereto. In other embodiments, the bridge dies 112 may be disposed on the carrier 10 in other ways. In addition, the bridge dies 112 may be of any suitable type of dies.

After the multiple bridge dies 112 are disposed, a package body 113 is formed to encapsulate the multiple bridge dies 112 (for example, in direct contact with the silicon substrate of the bridge dies 112). In an embodiment, the package body 113 may be formed by the following steps. First, a package material is formed to cover conductive bumps 112a of the bridge dies 112. The conductive bumps 112a may be disposed on a pad 112b and surrounded by an insulating layer 112c. Next, a planarization process is performed on the package material to form the package body 113. Therefore, a top surface of the package body 113 may be substantially coplanar with top surfaces of the conductive bumps 112a, but the disclosure is not limited thereto. Here, the package body 113 is, for example, a second insulating layer. In addition, the package body 113 may be a liquid compound or a granule type solid compound formed through an encapsulating process.

In FIG. 1A, multiple conductive connectors 114 may also be formed on the carrier 10. The multiple conductive connectors 114 may correspond to the multiple openings 111a of the layered structure 111 and surround the bridge dies 112. The multiple conductive connectors 114 and the multiple openings 111a are, for example, disposed in a one-to-one manner. In addition, top surfaces of the conductive connectors 114, a top surface of the package body 113, and the top surfaces of the conductive bumps 112a may be substantially coplanar, but the disclosure is not limited thereto.

In some embodiments, the material of the conductive connector 114 may include copper, aluminum, nickel or a combination thereof, and may be a conductive pillar formed by lithography, plating or photoresist stripping. However, the disclosure is not limited thereto. The conductive connector 114 may be formed of other suitable materials and formation methods depending on the actual design needs.

In an embodiment, the conductive connectors 114 are formed before the multiple bridge dies 112 are disposed and the package body 113 is formed. In another embodiment, the conductive connectors 114 are formed after the multiple bridge dies 112 are disposed and before the package body 113 is formed. In yet another embodiment, the conductive connectors 114 are formed after the multiple bridge dies 112 are disposed and the package body 113 is formed.

Please continue to refer to FIG. 1A. A circuit layer 115 (for example, is in direct contact with the package body 113 and the conductive connectors 114) is formed on the carrier 10. The package body 113 is disposed between the circuit layer 115 and the layered structure 111. In the embodiment, the circuit layer 115 may be a multi-layer structure. For example, the circuit layer 115 may include multiple dielectric layers 115a and multiple patterned conductive layers 115b that are stacked on each other. The patterned conductive layers 115b may reconfigure wires that are configured for packaged signal transmission.

In some embodiments, the material of the dielectric layer 115a may include silicon oxide, silicon nitride, silicon carbide, silicon oxynitride, polyimide, benzocyclobutene, and may be formed by spin-on coating, chemical vapor deposition (CVD) or plasma-enhanced chemical vapor deposition (PECVD).

In some embodiments, the material of the patterned conductive layer 115b may include copper, aluminum, nickel, gold, silver, tin or a combination thereof, and may be formed by sputtering, evaporation, electro-less plating or electroplating. However, the disclosure is not limited thereto. The dielectric layer 115a and the patterned conductive layer 115b may be formed of other suitable materials and formation methods according to the actual design needs.

Please refer to FIG. 1B. After the circuit layer 115 is formed, another carrier 20 and another release layer 21 are bonded to the circuit layer 115. A part of the circuit layer 115 may be optionally embedded in the release layer 21. Next, the carrier 10 is removed through the release layer 11 to expose a bottom surface 111b of the layered structure 111 and bottom surfaces 114b of the conductive connectors 114. The carrier 20 and the release layer 21 are similar to the carrier 10 and the release layer 11, and will not be described again here. Here, the release layer 11 and the carrier 10 may be peeled off from the layered structure 111 and the conductive connectors 114 by being exposed to a UV laser. In present embodiment, the release layer 21 may not provide adhesion function, for this reason, an adhesive layer (not shown) may be formed between the circuit layer 115 and the release layer 21.

Please refer to FIG. 1C. The structure shown in FIG. 1B is flipped upside down, so that the multiple bridge dies 112, the package body 113 and the conductive connectors 114 are displayed on/above the circuit layer 115. Then, multiple connection terminals 116 are formed on the bottom surfaces 114b of the conductive connectors 114 and the bottom surface 111b of the layered structure 111.

Furthermore, the connection terminals 116 may include multiple conductive terminals 116a and multiple dummy terminals 116b. The conductive terminals 116a may be in direct contact with the conductive connectors 114 and electrically connected, and the dummy terminals 116b may be in direct contact with the layered structure 111 and electrically insulated. Here, the dummy terminals 116b may be dummy bumps. Through the design of the dummy terminals 116b, in the embodiment where the terminals are produced using an electroplating process, the distribution of terminals on the entire plane that needs to be electroplated may be more uniform, in order to obtain a more uniform electroplating current distribution, and heights of the terminals formed may also be more uniform. In this way, a good terminal coplanarity may be obtained. Alternatively, the design of the dummy terminals 116b may have the effect of dispersing stress, so that in a condition where there is a temperature difference due to high and low temperature changes generated during subsequent component operations and/or reliability testing, the stress caused by the mismatch of thermal expansion coefficients (CTE) all acting on the conductive terminals 116a that are functional may be avoided, thereby effectively improving the life span and performance of the product as well as enhancing the performance of the product during reliability testing.

For example, the dummy terminals 116b may disperse the stress generated by the mismatch of thermal expansion coefficients (CTE) between the interposer modules 110 and the substrate 120, and may also subsequently reduce the probability of breaking even failure of the conductive terminals 116a due to the mismatch of thermal expansion coefficients (CTE) between the interposer modules 110 and the substrate 120. However, the disclosure is not limited thereto. The dummy terminals 116b may also be configured to disperse stress generated in other processes.

In some embodiments, the dummy terminals 116b are in direct contact with the layered structure 111. For example, when the layered structure 111 is a single-layer structure, the dummy terminals 116b may be in direct contact with a bottom surface of the layered structure 111 (relative to a top surface in FIG. 1A). When the layered structure 111 is a redistribution layer structure, the dummy terminals 116b may be in direct contact with a bottom insulating layer of the layered structure 111 (relative to a top insulating layer in FIG. 1A). In other words, when the layered structure 111 is a single-layer structure, the adhesive layer 12 and the dummy terminals 116b are respectively in direct contact with opposite surfaces of the layered structure 111. When the layered structure 111 is a redistribution layer structure, the adhesive layer 12 and the dummy terminals 116b are respectively in direct contact with insulating layers (the top insulating layer and the bottom insulating layer) on two opposite sides of the redistribution layer structure.

Please refer to FIG. 1D. After the connection terminals 116 are formed, the carrier 20 is removed through the release layer 21 to expose another surface of the circuit layer 115 relative to the surface where the bridge dies 112 are disposed. Here, the release layer 21 and the carrier 20 may be peeled off from the circuit layer 115 by being exposed to a UV laser.

Please refer to FIG. 1E. Next, a singulation process is performed to obtain multiple interposer modules 110 (singulated). The singulation process may be performed by a rotating blade or a laser beam. After the singulation process is performed and before the substrate 120 is bonded, an inspection and testing step may be performed on the interposer module 110 that is singulated to reduce the probability of negative impact caused by poor quality on a chip module 130 that is subsequently bonded thereon, but the disclosure is not limited thereto.

Please refer to FIG. 1F. The substrate 120 is provided, and the interposer module 110 (singulated) is disposed on the substrate 120. Next, the chip module 130 is disposed on the interposer module 110 so that the chip module 130 is electrically connected to the substrate 120 through the interposer module 110. In the embodiment, the chip module 130 is, for example, composed of multiple isolated chiplets (three chiplets 131 are schematically illustrated in FIG. 1F). Here, the three chiplets 131 may have the same function or different functions according to the actual design needs, which is not limited by the disclosure. For example, the chiplet 131 may be a logic chip, a memory chip, or a combination thereof.

In the embodiment, multiple external terminals 121 are further formed on the surface (such as the bottom surface) of the substrate 120 relative to the interposer module 110 to connect with other components (such as electrical connections or virtual connections) in subsequent processes.

In FIG. 1F, the interposer module 110 and the substrate 120 may be bonded through the multiple conductive terminals 116a and the dummy terminals 116b, and the chip module 130 and the interposer module 110 may be bonded through multiple conductive terminals 130a. The chip module 130 is electrically connected to the substrate 120 through the conductive terminals 130a, the circuit layer 115 in the interposer module 110, the conductive connectors 114 in the interposer module 110, and the conductive terminals 116a. Here, the conductive terminal 116a is, for example, a first conductive terminal, and the conductive terminal 130a is, for example, a second conductive terminal.

It should be noted that both the conductive terminals 116a and the dummy terminals 116b are in direct contact with a top metal layer of the substrate 120 to achieve the effect of dispersing stress. The top metal layer part to which the conductive terminals 116a are connected is a functional pad, so that the conductive terminals 116a are electrically connected to the functional external terminals 121 underneath. The top metal layer part to which the dummy terminals 116b are connected is a dummy pad, so that the dummy terminals 116b are not electrically connected (electrically insulated) with the functional external terminals 121 underneath, or so that the dummy terminals 116b are coupled to the dummy external terminals 121 underneath, that is, the external terminals 121 may include functional components and dummy components, but the disclosure is not limited thereto.

In an embodiment, before the interposer module 110 is bonded, steps for an inspection test may be performed on the substrate 120 to reduce the probability of negative impact caused by poor quality on the chip module 130 that is subsequently bonded thereon, but the disclosure is not limited thereto.

In an embodiment, there is a gap between the adjacent chiplets 131 in the chip module 130, and signals may be transmitted through the bridge dies 112, but the disclosure is not limited thereto.

In some embodiments, the substrate 120 may be an ABF substrate or the like. However, it should be noted that the number of dielectric layers in the substrate 120 and the design of the conductive circuit (such as perforations) in FIG. 1F are only schematic illustrations. The disclosure does not limit the type of the substrate 120. As long as the substrate 120 may provide signal transmission functions needed in the product, the embodiments all belong to the protection scope of the disclosure.

Please refer to FIG. 1G. The connections terminal 116 (including the conductive terminals 116a and the dummy terminals 116b) are cladded through a protective member 151A, and the conductive terminals 130a are cladded through a protective member 152A. The protective member 151A may be in direct contact with a top surface 120t of the substrate 120. The protective member 152A may be separated from the substrate 120 through the interposer module 110.

After the foregoing process, the production of a package structure PKG1 of the embodiment may be basically completed. Since the chip module 130 is not first disposed on the interposer module 110 of a wafer level, and most of the processes in the package structure PKG1 have been completed when disposed, the number of processes that the chip module goes through may be decreased, and the risk of yield loss in the process may be reduced. At the same time, the stress may be dispersed during the process based on the design of the dummy terminals 116b. Accordingly, the yield of the package structure PKG1 of the embodiment is effectively improved, thereby ensuring good quality. Here, the interposer module 110 of a wafer-level is, for example, the interposer module 110 without singulation in FIG. 1D.

In addition, the unsingulated interposer wafer warpage and unevenness caused by multi layers (such as dielectric layer, RDL layer and and/or molding layer) may impact the chiplets placement process window and yield. On the other hand, the problem of conductive terminals on the chip unable to effectively align with an interposer structure underneath may also occur, so the risk of the process is higher, and the yield is difficult to control. However, with the design of the process steps in FIG. 1A to FIG. 1G, the bonding process of chiplets with thin gaps may be limited to be performed in a smaller region (a dimension of the interposer module 110 that is singulated). Therefore, a wider process window is allowed, thereby reducing the probability of the foregoing problem from occurring.

In an embodiment, the dummy terminals 116b correspond to the bridge dies 112 in a stacking direction D of the substrate 120, the interposer module 110 and the chip module 130. For example, orthographic projections of the dummy terminals 116b on the substrate 120 overlap with orthographic projections of the bridge dies 112 on the substrate 120, but the disclosure is not limited thereto.

In addition, as shown in FIG. 1G, the material of the protective member 151A is different from the material of the protective member 152A, and the protective member 151A and the protective member 152A are formed in different processes. For example, the material of the protective member 151A is selected from a capillary underfill filling material (CUF), and the material of the protective member 152A is selected from a non-conductive film (NCF). For example, in FIG. 1G, since the capillary underfill filling material is formed by performing a dispensing process, filling the gaps between the connection terminals 116 through the fluidity and capillary phenomenon of the colloid, and at the same time, also overflowing upward to form on a side wall of the interposer module 110, so the protective member 151A may have a trapezoidal profile. On the other hand, since the non-conductive film is formed by performing a film sticking process, before the chip module 130 is bonded to the interposer module 110, the conductive terminals 130a on the chiplets 131 are first attached to a sheet-like dry film material, and then flip-chip bonding of the chiplets 131 is performed through heat and pressure. At the same time, the conductive terminals 130a may be protected by the protective member 152A. Therefore, the flip-chip bonding method used for a non-conductive film is thermal compression bond (TCB). The protective member 152A may form an arc edge caused by the extrusion of the dry film material, and may not clad on side walls (such as upper parts) of the chiplets 131 in this way. That is, based on the selection of different materials, the protective member 151A and the protective member 152A may have different forms, but the disclosure is not limited thereto.

In an embodiment, the capillary underfill filling material and the non-conductive film may have their respective advantages in different conditions. For example, when there is a high aspect ratio between the chiplets 131, such as a large dimension of the chiplet 131 and/or a small spacing between the chiplets 131 (such as 50 microns to 150 microns), the capillary underfill filling material may easily clad the side walls between the chiplets 131 and be in contact with a large area of the substrate material (such as silicon) in the chiplets 131. In this way, in a condition where it is easy to generate poor adhesion or trapped voids between the capillary underfill filling material and the substrate material, and/or the capillary underfill filling material itself is insufficient in strength, negative impact, such as delamination and crack, may occur during reliability testing, reducing product reliability. In this condition, the non-conductive film has advantages since the foregoing risks may be avoided. On the other hand, since it is difficult for the non-conductive film to clad taller conductive terminals, in a condition where heights (solder joint height) of the conductive terminals 130a bonded to the chiplets 131 are higher (such as a height greater than 40 microns), the capillary underfill filling material has advantages. Therefore, the disclosure does not limit the material of the protective member. The material may be determined according to the actual design needs.

In the embodiment, the non-conductive film is used between the chiplets 131 and the interposer module 110 to shrink the dimension of the interposer module 110, but the disclosure is not limited thereto. In other embodiments, when the non-conductive film is used between the interposer module 110 and the substrate 120, the dimension of the substrate 120 may be shrunk.

In the embodiment, after the chip module 130 is disposed on the interposer module 110, an encapsulating process and a singulation process are not performed, and a side surface 130s and a top surface 130t of the chiplet 131 in the chip module 130 may be completely exposed. In this way, the heat dissipation capacity may be significantly improved. In addition, since no encapsulating material may be formed subsequently, the gap between the chiplets 131 in the chip module 130 may be effectively reduced (such as less than or equal to 50 microns), thereby making the package structure PKG1 more advantageous in miniaturization, but the disclosure is not limited thereto.

In an embodiment, the chip module 130 is composed of the multiple chiplets 131 that are isolated. Since the cost of the chiplets 131 is higher, a probe card test may be first performed before the chiplets 131 are disposed on the interposer module 110 to select known good dies (KGD). In this way, a condition where other chiplets 131 fail to operate due to damages of some chiplets 131 in the chip module 130 may be avoided, but the disclosure is not limited thereto. Here, the known good die may be a semiconductor die that has been tested, inspected, and passed in terms of function orreliability, and is known to be able to achieve all designed properties and operating states after a potential of a power supply is applied.

In some embodiments, the conductive bumps 112a, the connection terminals 116, and the conductive terminals 130a may respectively include conductive pillars, conductive plug solder balls, or combinations thereof. The material may be copper or the like. The solder balls may be formed by a ball placement process and/or a reflow process, but the disclosure is not limited thereto. In some alternative embodiments, the conductive bumps 112a, the connection terminals 116, and the conductive terminals 130a may use other possible forms or shapes based on the design needs, and may have the same or different appearances from each other.

In some embodiments, the package body 113 may be formed of an insulating material such as epoxy resin or other suitable resin, and for example, is a molding compound formed by a molding process, but the disclosure is not limited thereto. The package body 113 may be formed by other suitable materials and methods.

It must be noted here that the following embodiments use the reference numerals and part of the content of the foregoing embodiments. The same or similar reference numerals are used to represent the same or similar elements, and the description of the same technical content is omitted. For descriptions of the omitted parts, please refer to the foregoing embodiments, and the following embodiments will not repeat again.

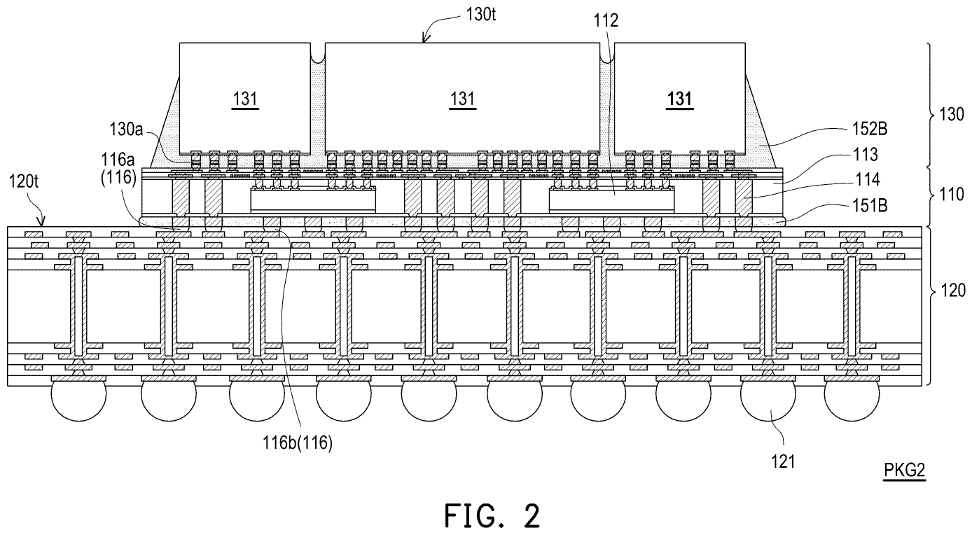

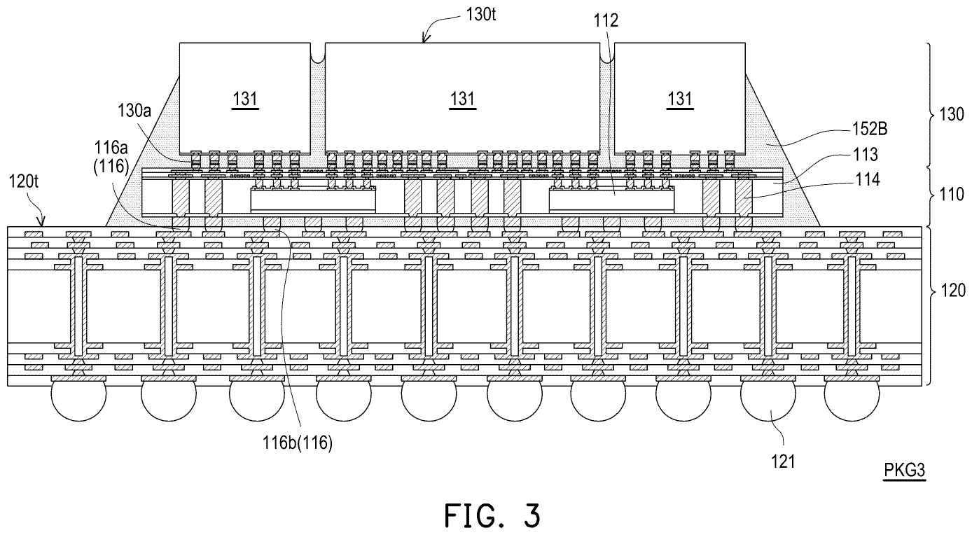

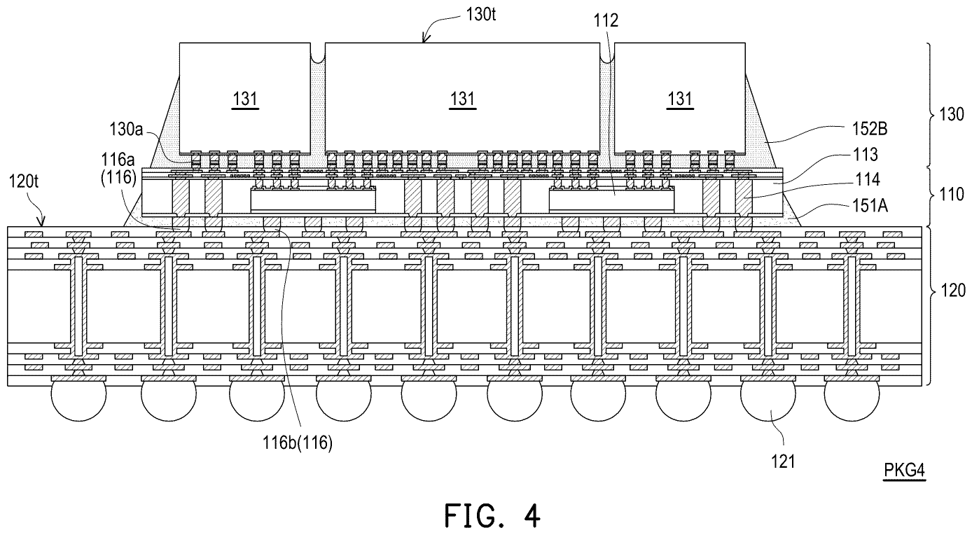

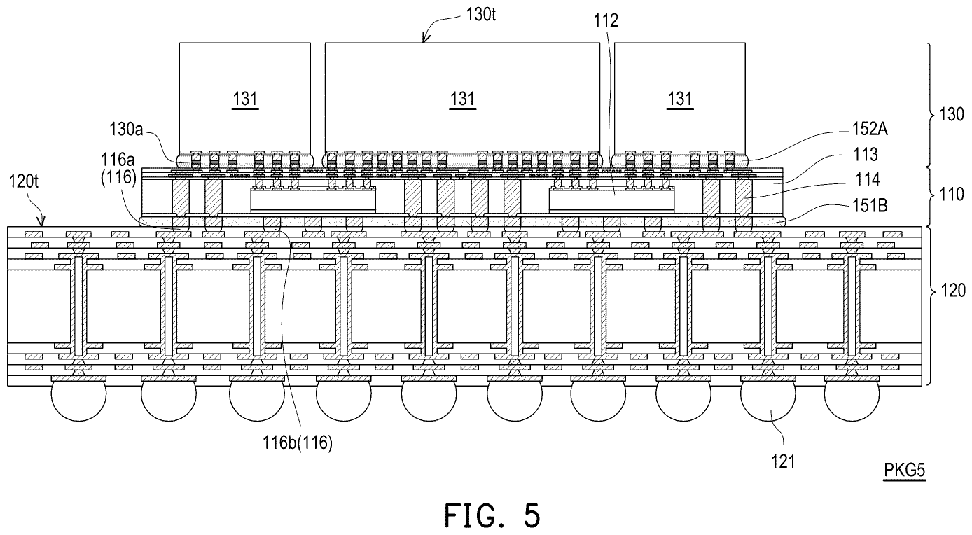

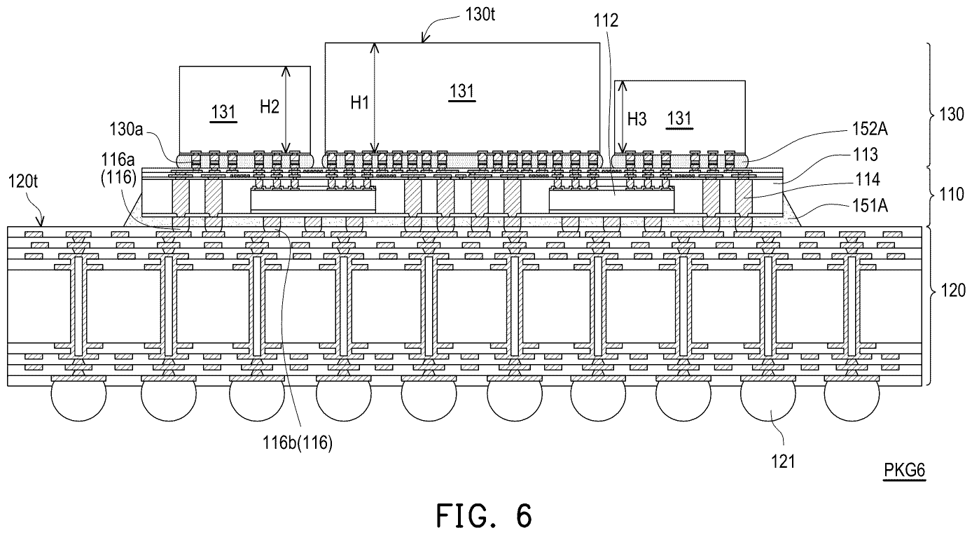

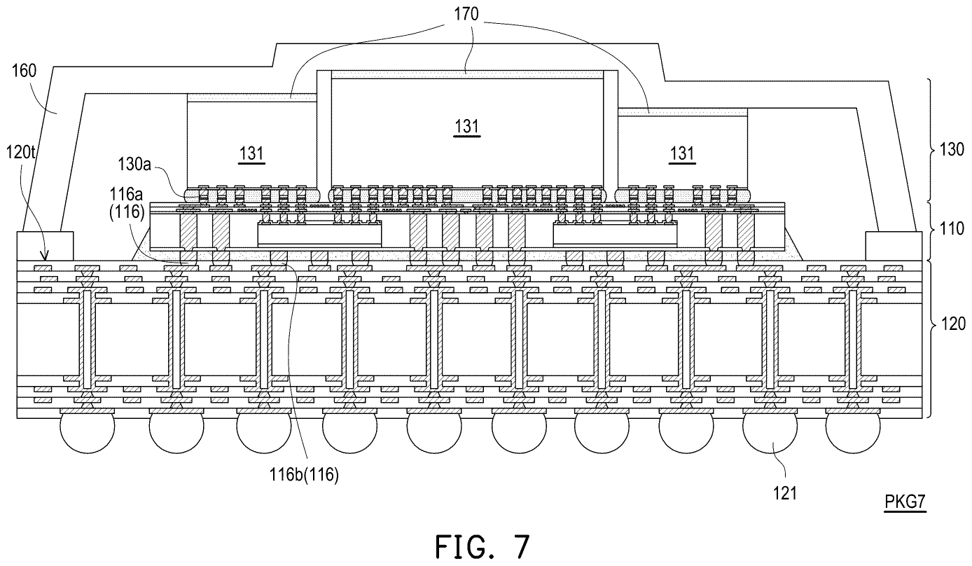

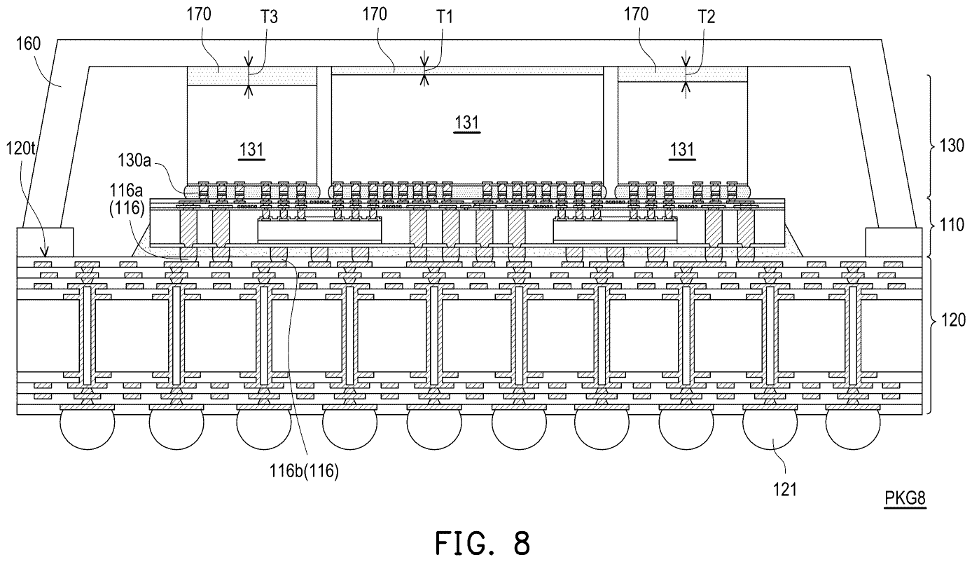

FIG. 2, FIG. 3, FIG. 4, FIG. 5, FIG. 6, FIG. 7, and FIG. 8 are partial cross-sectional schematic diagrams of a package structure according to some embodiments of the disclosure.

Please refer to FIG. 2. In the embodiment, a package structure PKG2 is similar to the package structure PKG1. The difference is that a protective member 151B is selected from a non-conductive film, and a protective member 152B is selected from a capillary underfill filling material. Therefore, the protective member 151B has an arc-shaped edge, and the protective member 152B has a trapezoidal profile. Furthermore, in the embodiment, a flip-chip bonding method when the capillary underfill filling material is used may be to first place the chiplets 131 in position, and then bond in a reflowing manner, and then form the capillary underfill filling material through a dispensing process, that is, the protective member 152B may be formed after the chip module 130 is bonded to the interposer module 110.

Please refer to FIG. 3. In the embodiment, a package structure PKG3 is similar to the package structure PKG2. The difference is that the connection terminals 116 and the conductive terminals 130a are simultaneously cladded at one time with the protective member 152B selected from a capillary underfill filling material (formed during a same manufacturing process). In the embodiment, the protective member 152B clads the connection terminals 116 (including the conductive terminals 116a and the dummy terminals 116b) and the conductive terminals 130a, so that the connection terminals 116 (including the conductive terminals 116a and the dummy terminals 116b) and the conductive terminals 130a are retracted in the protective member 152B. In this way, components such as the connection terminals 116 (including the conductive terminals 116a and the dummy terminals 116b) and the conductive terminals 130a may be simultaneously protected at one time, significantly reducing the cost of materials, but the disclosure is not limited thereto.

Please refer to FIG. 4. In the embodiment, a package structure PKG4 is similar to the package structure PKG1 and the package structure PKG2. The difference is that the connection terminals 116 are cladded with the protective member 151A selected from a capillary underfill filling material, and the conductive terminals 130a are cladded with the protective member 152B selected from the capillary underfill filling material.

Please refer to FIG. 5. In the embodiment, a package structure PKG5 is similar to the package structure PKG1 and the package structure PKG2. The difference is that the connection terminals 116 are cladded with the protective member 151B selected from a non-conductive film, and the conductive terminals 130a are cladded with the protective member 152A selected from the non-conductive film.

Please refer to FIG. 6. In the embodiment, a package structure PKG6 is similar to the package structure PKG1. The difference is that since an encapsulating process and a planarization process are not performed, the multiple chiplets 131 in the chip module 130 may have different heights. In addition, in the embodiment, the heights of the multiple chiplets 131 may all be different, as shown in FIG. 6, having a first height H1, a second height H2, and a third height H3 that decrease in sequence, but the disclosure is not limited thereto. In an embodiment not illustrated, only some of the heights of the multiple chiplets 131 in the chip module 130 may be different. For example, the heights of two of the three chiplets 131 are the same but are different from another one.

Please refer to FIG. 7. In the embodiment, a package structure PKG7 is similar to the package structure PKG1. The difference is that: the package structure PKG7 further includes a cover 160. The cover 160 at least covers a back surface of the chip module 130 relative to an active surface. Therefore, the cover 160 may protect the electronic components in the package structure PKG7, and may also serve as a heat sink to provide additional heat dissipation functions. In an embodiment, the cover 160 composes multiple cavities in the package structure PKG7.

In addition, in the embodiment, when the height difference is larger between the multiple chiplets 131 of the chip module 130, the cover 160 has a stepwise shape when viewed in cross section. The multiple chiplets 131 and the cover 160 may be bonded through a thermal interface (TIM) material 170 with substantially the same thickness, but the disclosure is not limited thereto.

Please refer to FIG. 8. In the embodiment, a package structure PKG8 is similar to the package structure PKG7. The difference is that there are the thermal interface materials 170 with different thicknesses between the cover 160 and each of the multiple chiplets 131 in the chip module 130 to apply in a condition where the height differences are smaller (such as less than 100 microns) between the multiple chiplets 131 in the chip module 130.

In the embodiment, the thicknesses of the multiple thermal interface materials 170 may all be different, as shown in FIG. 8, having a first thickness T1, a second thickness T2, and a third thickness T3 that increase in sequence, but the disclosure is not limited thereto. In an embodiment not illustrated, only some of the thicknesses of the multiple thermal interface materials 170 may be different. For example, the thicknesses of two of the three thermal interface materials 170 may be the same and are different from another one.

In the foregoing implementation, the back surface 130t of the chip module 130 may be further deposited to form a backside metal (BSM) (not illustrated). The backside metal may be pre-deposited on the back surface 130t before the chip module 130 is disposed to further improve the heat dissipation capability, but the disclosure is not limited thereto. Here, the material of the backside metal may be any suitable metal material with excellent heat dissipation efficiency, which is not limited by the disclosure.

In an embodiment not illustrated, the package structure further includes a metal ring. The metal ring may be located on a top surface of the substrate and surround the chip module. Therefore, the metal ring may protect the electronic components in the package structure and may also serve as a reinforcement to provide additional support, but the disclosure is not limited thereto.

In summary, since the number of processes that the chip module goes through may be decreased, the risk of yield loss in the process may be reduced, and at the same time, the stress in the process may be dispersed by the design of dummy terminals. Accordingly, the yield of the package structure of the disclosure is effectively improved, thereby ensuring good quality.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A package structure, comprising:
a substrate;
an interposer module, disposed on the substrate, wherein:
the interposer module comprises a first insulating layer, a second insulating layer, and a plurality of dummy terminals;
the first insulating layer is disposed between the second insulating layer and the substrate; and
the plurality of dummy terminals are in direct contact with the first insulating layer and the substrate; and
a chip module, disposed on the interposer module and electrically connected to the substrate through the interposer module; and
a plurality of external terminals, comprising a plurality of functional components, wherein the substrate is disposed between the plurality of dummy terminals and the plurality of external terminals, and the plurality of dummy terminals are electrically insulated the plurality of functional components.

2. The package structure according to claim 1, wherein the interposer module further comprises a plurality of bridge dies that are disposed on the first insulating layer through an adhesive layer, the second insulating layer encapsulates the plurality of bridge dies, and the plurality of dummy terminals correspond to the plurality of bridge dies in a stacking direction of the substrate, the interposer module and the chip module.

3. The package structure according to claim 2, wherein orthographic projections of the plurality of dummy terminals on the substrate overlap with orthographic projections of the plurality of bridge dies on the substrate.

4. The package structure according to claim 2, wherein the adhesive layer and the plurality of dummy terminals are respectively in direct contact with opposite surfaces of the first insulating layer.

5. The package structure according to claim 2, wherein the interposer module comprises a redistribution layer structure, the first insulating layer is a bottom insulating layer of the redistribution layer structure, and the adhesive layer is in direct contact with a top insulating layer in the redistribution layer structure relative to the first insulating layer.

6. The package structure according to claim 1, wherein the plurality of dummy terminals are in direct contact with a dummy pad of a top part of the substrate.

7. The package structure according to claim 1, wherein the external terminals further comprising a plurality of dummy components, wherein t the plurality of dummy terminals are coupled to the plurality of dummy components.

8. The package structure according to claim 1, further comprising a plurality of conductive terminals, wherein the plurality of conductive terminals are disposed between the interposer module and the substrate and surround the plurality of dummy terminals.

9. The package structure according to claim 1, further comprising a cover that is disposed on the substrate, wherein there is a thermal interface material between the cover and each of a plurality of chiplets in the chip module.

10. The package structure according to claim 9, wherein the plurality of chiplets in the chip module have different heights.

11. The package structure according to claim 10, wherein there is a thermal interface material with a different thickness between the cover and each of the plurality of chiplets in the chip module.

12. A manufacturing method of a package structure, comprising:
providing a substrate;
providing an interposer module, wherein the interposer module is singulated and comprises a plurality of dummy terminals;
disposing the interposer module on the substrate through the plurality of dummy terminals;
providing a chip module; and
disposing the chip module on the interposer module, wherein the chip module is electrically connected to the substrate through the interposer module.

13. The manufacturing method according to claim 12, wherein after the chip module is disposed on the interposer module, an encapsulating process and a singulation process are not performed.

14. The manufacturing method according to claim 12, further comprising:
bonding the interposer module and the substrate through a plurality of first conductive terminals;
bonding the chip module and the interposer module through a plurality of second conductive terminals; and
cladding the plurality of first conductive terminals and the plurality of second conductive terminals respectively through a first protective member and a second protective member.

15. The manufacturing method according to claim 14, wherein the first protective member and the second protective member are respectively formed through performing a dispensing process or a film sticking process.

16. The manufacturing method according to claim 14, wherein the first protective member and the second protective member are formed in different processes.

17. The manufacturing method according to claim 12, wherein steps of forming the interposer module comprise:
providing a first insulating layer;
disposing a plurality of bridge dies on the first insulating layer;
forming a second insulating layer and encapsulating the plurality of bridge dies;
forming the plurality of dummy terminals on the first insulating layer; and
performing a singulation process.

18. The manufacturing method according to claim 17, further comprising forming a plurality of conductive terminals to surround the plurality of dummy terminals.
